(19) United States
(12) Patent Application Publication
(10) Pub. No.: US 2026/0038571 A1
(43) Pub. Date: Feb. 5, 2026

(54) APPARATUSES, SYSTEMS AND METHODS FOR DATA BUFFER CONTROL

(71) Applicant: Micron Technology, Inc., Boise, ID (US)

(72) Inventors: Hyun Yoo Lee, Boise, ID (US); SeungWook Oh, Boise, ID (US)

(73) Assignee: Micron Technology, Inc., Boise, ID (US)

(21) Appl. No.: 19/281,350

(22) Filed: Jul. 25, 2025

Related U.S. Application Data
(60) Provisional application No. 63/677,815, filed on Jul. 31, 2024.

(51) Int. Cl. G11C 11/4076; G11C 11/4072; G11C 11/4093; G11C 11/4096

(52) U.S. Cl. CPC G11C 11/4076; G11C 11/4072; G11C 11/4093; G11C 11/4096

(57) ABSTRACT

A memory device includes data and command paths for various operations, such as read operations. A first counter circuit in the data path is configured to provide first count signals to a data buffer to input read data into the data buffer and a second counter circuit in the command path is configured to provide second count signals to the data buffer to output read data from the data buffer. Comparator and reset circuitry is configured to receive the first and the second count signals, compare a first count value that is based on the first count signal to a second count value that is based on the second count signal, and provide a reset signal to the first and second counter circuits when there is a mismatch between the first and second count values to reset the first and the second counter circuits.

### CROSS-REFERENCE TO RELATED APPLICATION

This application claims the filing benefit of U.S. Provisional Application No. 63/677,815, filed Jul. 31, 2024. This application is incorporated by reference herein in its entirety and for all purposes.

### BACKGROUND

A semiconductor memory device may include a number of memory cells which are used to store data represented by binary digits (or “bits”). The memory cells are typically arranged in an array and accessed based on row addresses and column addresses. When read operations are performed, data is read out of memory cells based on read commands supplied with row and column addresses that are used to select the memory cells. The read data may be stored in a data buffer after the read data is read out of the memory array. In some instances, the pulses in the read data that are output from the data buffer do not correspond to the pulses in the read data that were input into the data buffer, a condition known as a twisted data buffer. A twisted data buffer adversely impacts the performance of the semiconductor memory device or renders the semiconductor memory device unusable.

### BRIEF DESCRIPTION OF THE DRAWINGS

Non-limiting and non-exhaustive examples are described with reference to the following Figures. The elements of the drawings are not necessarily to scale relative to each other. Identical reference numerals have been used, where possible, to designate identical features that are common to the Figures.

FIG. 1 illustrates a block diagram of an example semiconductor device according to an embodiment of the disclosure;

FIG. 2 illustrates an example timing diagram of a first control signal and a second control signal that may be generated during read operations;

FIG. 3 illustrates an example timing diagram of a first erroneous first control signal and the second control signal that may be generated during read operations;

FIG. 4 illustrates an example timing diagram of a second erroneous first control signal and the second control signal that may be generated during read operations;

FIG. 5 illustrates an example timing diagram of the first control signal and an erroneous second control signal that may be generated during read operations;

FIG. 6 illustrates a block diagram of an example data path and an example command path for read operations in a memory device according to an embodiment of the disclosure;

FIG. 7 illustrates a block diagram of example comparator and reset circuitry according to an embodiment of the disclosure; and

FIG. 8 illustrates a flowchart of an example method of operating a memory device according to an embodiment of the disclosure.

### DETAILED DESCRIPTION

Embodiments described herein provide systems and methods for detecting and correcting a twisted data buffer. In one embodiment, the data buffer is a first in, first out (FIFO) data buffer. Semiconductor memory devices typically include a data path and a command path for various operations, such as read operations. For read operations, the data path is configured to provide data stored in a memory array to external data terminals (i.e., data terminals to provide read data to a controller or a host device). The command path is configured to receive read commands and provide internal command and control signals to various circuitry to provide the read data to the external data terminals.

During read operations, one or more first counter circuits in the data path provide first count signals to one or more data buffers to cause read data to be input into the data buffer(s), and one or more second counter circuits in the command path provide second count signals to the one or more data buffers to cause the read data to be output from the data buffer(s). When read operations are not being performed and the one or more data buffers are in an idle state (i.e., not inputting and outputting read data), comparator and reset circuitry operably connected or coupled to the first and the second counter circuits receives the first and the second count signals. The comparator and reset circuitry compares a first count value that is based on the first count signal to a second count value that is based on the second count signal. The comparator and reset circuitry provides a reset signal to the first counter circuit(s) in the data path and to the second counter circuit(s) in the command path when there is a mismatch between the first count value and the second count value. The reset signal is configured to reset or initialize the first counter circuit(s) and the second counter circuit(s). The first counter circuit(s) and the second counter circuit(s) may be reset to any count value, such as zero (0). Read operations may be performed after the first counter circuit(s) and the second counter circuit(s) are reset. The pulses in read data as output from the data buffer correspond to the pulses in read data as input into the data buffer based on the reset of the first and the second counter circuit(s).

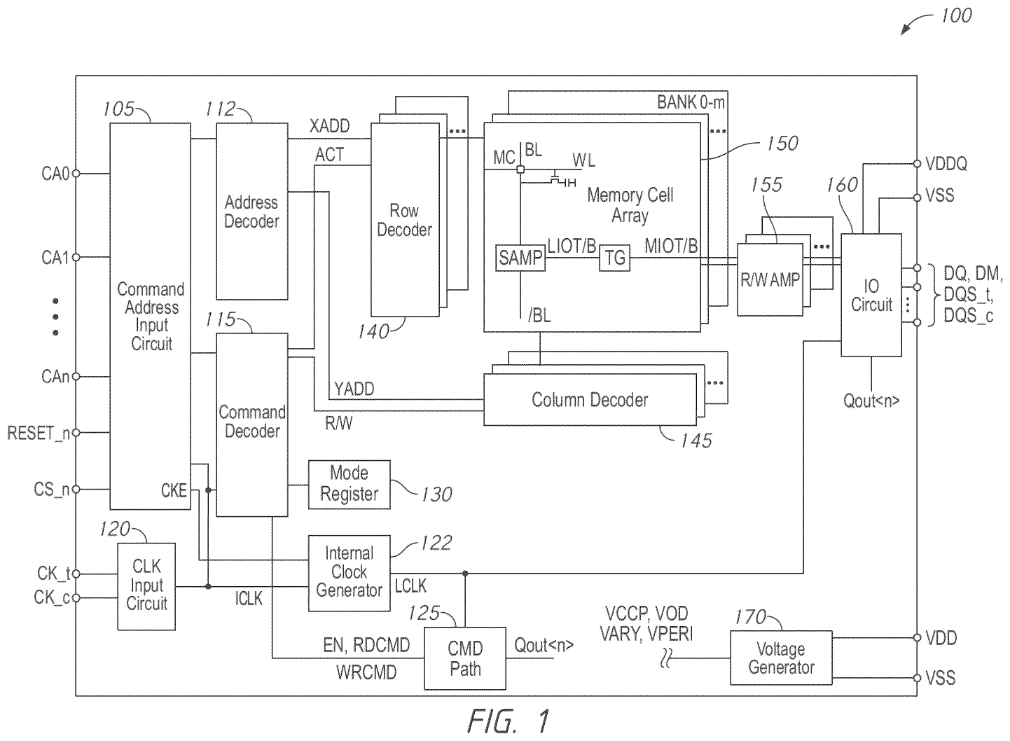

FIG. 1 illustrates a block diagram of a semiconductor device 100 according to an embodiment of the disclosure. The semiconductor device 100 may include, without limitation, a dynamic random-access memory (DRAM), a double data rate (DDR) memory, a low power double data rate (LPDDR) memory, or other type of memory.

The semiconductor device 100 includes a memory array 150. The memory array 150 is shown as including a plurality of memory banks. In the embodiment of FIG. 1, the memory array 150 is shown as including memory banks BANK0-BANKm. Each memory bank includes a plurality of word lines WL, a plurality of bit lines BL and /BL, and a plurality of memory cells MC arranged at intersections of the plurality of word lines WL and the plurality of bit lines BL and /BL. Selection of the word line WL is performed by a row decoder 140 and selection of the bit lines BL and /BL is performed by a column decoder 145. In the illustrated embodiment, the row decoder 140 includes a respective row decoder for each memory bank and the column decoder 145 includes a respective column decoder for each memory bank. The bit lines BL and /BL are coupled to a respective sense amplifier (SAMP). Read data from the bit line BL or /BL is amplified by the sense amplifier SAMP and transferred to read/write amplifiers 155 over complementary local data lines (LIOT/B), transfer gate (TG), and complementary main data lines (MIOT/B). Conversely, write data output from the read/write amplifiers 155 is transferred to the sense amplifier SAMP over the complementary main data lines MIOT/B, the transfer gate TG, and the complementary local data lines LIOT/B, and written in the memory cell MC coupled to the bit line BL or /BL.

A mode register 130 stores information, for example, configuration and status information for the semiconductor device 100. The mode register 130 may be accessed through mode register read commands and mode register write commands. The mode register access commands cause the semiconductor device 100 to perform mode register read operations and mode register write operations. A mode register read command causes the semiconductor device 100 to provide information stored by the mode register that is accessed, and a mode register write command causes the semiconductor device 100 to store information in the mode register that is accessed. The mode register 130 may include several mode registers, with each of the mode registers corresponding to a mode register address and storing different types of information.

The semiconductor device 100 may employ a plurality of external terminals that include command and address terminals (CA0-CAn) to receive commands and addresses, an external Reset_n signal and an external control CS_n signal. The external terminals may further include clock terminals to receive clocks CK_t and CK_c, and data clocks DQS_t and DQS_c, data terminals DQ, and power supply terminals to receive power supply potentials VDD, VSS, and VDDQ.

The clock terminals are supplied with external clocks CK_t and CK_c that are provided to a CLK input buffer 120. The external clocks may be complementary (e.g., 180 degrees out of phase). The CLK input buffer 120 generates an internal clock ICLK based on the CK_t and CK_c clocks. The ICLK clock is provided to a command decoder 115, a command/address input circuit 105, and to an internal clock generator 122. The internal clock generator 122 provides various internal clocks LCLK based on the ICLK clock. The LCLK clocks may be used for timing operation of various internal circuits.

The power supply terminals are supplied with power supply potentials VDD and VSS. The power supply potentials VDD and VSS are supplied to an internal voltage generator circuit 170. The internal voltage generator circuit 170 generates various internal potentials VCCP, VOD, VARY, VPERI, and the like based on the power supply potentials VDD and VSS supplied to the power supply terminals. The internal potential VCCP is mainly used in the row decoder 140, the internal potentials VOD and VARY are mainly used in the sense amplifiers SAMP included in the memory array 150, and the internal potential VPERI is used in many peripheral circuit blocks.

The power supply terminals are also supplied with power supply potentials VDDQ and VSS. The power supply potentials VDDQ and VSS are supplied to the input/output circuit 160. The power supply potentials VDDQ and VSS supplied to the power supply terminals may be the same potentials as the power supply potentials VDD and VSS supplied to the power supply terminals in an embodiment of the disclosure. The power supply potentials VDDQ and VSS supplied to the power supply terminals may be different potentials from the power supply potentials VDD and VSS supplied to the power supply terminals in another embodiment of the disclosure. The power supply potentials VDDQ and VSS supplied to the power supply terminals are used for the input/output circuit 160 so that power supply noise generated by the input/output circuit 160 does not propagate to the other circuit blocks.

The CA terminals (e.g., CA0-CAn) may be supplied with commands and memory addresses from, for example, a memory controller. The memory addresses supplied to the CA terminals are transferred to an address decoder 112 via the command/address input circuit 105. The address decoder 112 receives the address and supplies a decoded row address XADD to the row decoder 140 and supplies a decoded column address YADD to the column decoder 145.

The commands received at the CA terminals may be provided as internal command signals to the command decoder 115 via the command/address input circuit 105. Example commands that may be received at the CA terminals include access commands for accessing the memory (such as read commands for performing read operations and write commands for performing write operations), mode register write and read commands for performing mode register write and read operations, power down commands, as well as other commands and operations.

The command decoder 115 includes circuits to decode the internal command signals to generate various internal signals for performing operations. For example, the command decoder 115 may generate a row command signal ACT to select a word line, a column command signal R/W to select a bit line, a read command signal RDCMD based on a read command, and a write command signal WRCMD based on a write command.

The various internal signals, such as the RDCMD signal, are provided to a command path 125. The command path 125 may include a read command path that receives the RDCMD signals and provides control signals Qout<n>. The Qout<n> signals are provided to the input/output circuit 160 to perform operations related to the read commands, such as providing read data to the external DQ terminals.

For example, read data is read from a memory cell in the memory array 150 corresponding to a row address and a column address when a read command is received and the row address and the column address are timely supplied with an ACT command and/or the read command. The read command is provided to the command decoder 115 and read data is read from memory cells in the memory array 150 and provided to the input/output circuit 160 via the read/write amplifiers 155. The command decoder 115 provides internal RDCMD signals to the command path 125, which provides control signals (i.e., Out<n>) to the input/output circuit 160 so that the read data is output to outside from the external data terminals DQ (e.g., output to a controller or a host). The DQS_t and DQS_c clocks are provided externally from clock terminals for timing provision of the read data by the input/output circuit 160. The external data terminals DQ include several separate terminals, each providing a bit of data synchronized with a clock edge of the DQS_t and DQS_c clocks.

Write data supplied to the data terminals DQ is written to a memory cell in the memory array 150 corresponding to a row address and a column address when a write command is received and the row address and the column address are timely supplied with an ACT command and/or the write command. The command decoder 115 provides internal WRCMD signals to the command path 125, which provides control signals to the input/output circuit 160 so that the write data is received by input receivers in the input/output circuit 160 and supplied to the memory array 150 via the read-write amplifiers 155. DQS_t and DQS_c clocks are also provided to the external clock terminals (e.g., by a controller) for timing the receipt of the write data by the input receivers of the input/output circuit 160. The write data is supplied via the input/output circuit 160 to the read/write amplifiers 155, and by the read/write amplifiers 155 to the memory array 150 to be written into the memory cell that corresponds to the row address and the column address supplied with the write command. As previously described, the external terminals DQ include several separate terminals. With reference to a write operation, each external terminal DQ concurrently receives a bit of data synchronized with a clock edge of the DQS_t and DQS_c clocks. A data mask may be provided to the data terminals DM to mask portions of the data when written to memory.

The semiconductor device 100 includes a data path along with the command path. For read operations, the data path is configured to provide read data to the external data terminals DQ, and the command path is configured to receive a RDCMD signal and provide internal command and control signals to various circuitry to provide the read data to the external data terminals DQ. For example, in FIG. 1, the data path includes the memory array 150 and signal lines and circuits to provide data to and/or from the memory array 150, and the command path includes the command path 125. As described earlier, control signals can be provided by the command path 125 during read operations to control the output of the read data to the external data terminals DQ. In some instances, errors can occur in the control signals, which may disrupt the output of the read data and cause data buffers to become twisted.

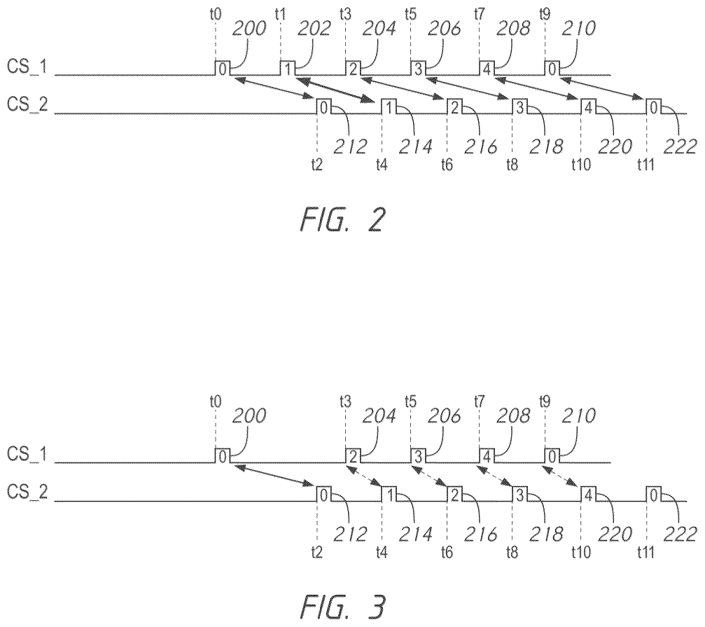

FIG. 2 illustrates an example timing diagram of a first control signal CS_1 and a second control signal CS_2 that may be generated during read operations. In one embodiment, the CS_1 signal is generated in a data path and the CS_2 is generated in a command path during read operations (e.g., the command path 125 of the semiconductor device 100 of FIG. 1). In FIG. 2, the read operations are performed sequentially (i.e., the multiple pulses). The CS_1 signal is received by a data buffer and is used to input read data into the data buffer, and the CS_2 signal is received by the data buffer and is used to output read data from the data buffer. The data buffer may be one or more FIFO data buffers in some embodiments.

The CS_1 signal begins to toggle between a first signal level (e.g., “0” or low) and a second signal level (e.g., “1” or high) at time to. The input of read data into the data buffer is synchronized with each pulse 200, 202, 204, 206, 208, 210 at respective times t0, t1, t3, t5, t7, t9 (e.g., the rising edge of each pulse 200, 202, 204, 206, 208, 210). The CS_2 signal begins to toggle between the first signal level and the second signal level at time t2. The output of read data from the data buffer is synchronized with each pulse 212, 214, 216, 218, 220, 222 at respective times t2, t4, t6, t8, t10, t11 (e.g., the rising edge of each pulse 212, 214, 216, 218, 220, 222). Each pulse 200, 202, 204, 206, 208, 210 in the CS_1 signal has a corresponding pulse 212, 214, 216, 218, 220, 222 in the CS_2 signal, respectively. Thus, read data is input to the data buffer in response to a pulse of CS_1 and that read data is output from the data buffer in response to a corresponding pulse of CS_2. For example, in FIG. 2, read data input into the data buffer at time t0 is output from the data buffer at time t2, read data input into the data buffer at time t1 is output from the data buffer at time t4, read data input into the data buffer at time t3 is output from the data buffer at time t6, read data input into the data buffer at time t5 is output from the data buffer at time t8, read data input into the data buffer at time t7 is output from the data buffer at time t10, read data input into the data buffer at time t9 is output from the data buffer at time t11, and so on.

FIG. 3 illustrates an example timing diagram of a first erroneous first control signal CS_1 and the second control signal CS_2 that may be generated during read operations. The CS_1 signal begins to toggle between the first signal level and the second signal level at time t0. Read data is input and stored in the data buffer based on each pulse 200, 204, 206, 208, 210 at respective times t0, t3, t5, t7, t9. However, there is an error in the CS_1 signal. A pulse (i.e., the pulse 202) was not received by the data buffer between times t0 and t3 (i.e., at time t1), so no read data was stored in the data buffer at that time. In some instances, the missing pulse may be caused by process variations during fabrication of one or more circuits in the data path (e.g., transistors), large RC loading, and/or a relatively large number of gate delays in the data path.

The CS_2 signal begins to toggle between the first signal level and the second signal level at time t2. Read data is output from the data buffer based on each pulse 212, 214, 216, 218, 220, 222 at respective times t2, t4, t6, t8, t10, t11. However, because a pulse in the CS_1 signal was not received between times t0 and t3, each pulse in the CS_2 signal does not have a corresponding pulse in the CS_1 signal. The read data output from the data buffer after time t2 is not the expected read data to be output from the data buffer. For example, the read data input into the data buffer at time t3 should be output from the data buffer at time t6 (see FIG. 2), but the read data is actually output at time t4. Thus, the data buffer is twisted, and the read data is not output from the data buffer in the same order that the read data was input into the data buffer.

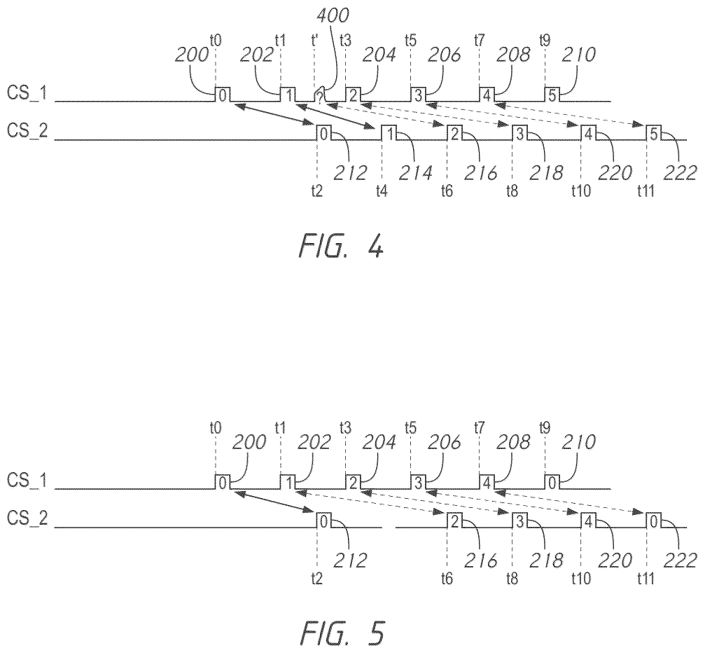

FIG. 4 illustrates an example timing diagram of a second erroneous first control signal CS_1 and the second control signal CS_2 that may be generated during read operations. The CS_1 signal begins to toggle between the first signal level and the second signal level at time t0. Read data is input and stored in the data buffer based on each pulse 200, 202, 204, 206, 208, 210 at respective times t0, t1, t3, t5, t7, t9. However, the CS_1 signal includes an additional pulse 400 at time t′. Thus, information may be input and stored in the data buffer based on the additional pulse 400, for example, the information may be the read data that is input at time t1, or the information may be unknown data. In some instances, the additional pulse 400 may be generated as a result of crosstalk between two closely placed signal lines.

The CS_2 signal begins to toggle between the first signal level and the second signal level at time t2. Read data is output from the data buffer based on each pulse 212, 214, 216, 218, 220, 222 at respective times t2, t4, t6, t8, t10, t11. However, due to the additional pulse 400 in the CS_1 signal, each pulse in the CS_1 signal does not have a corresponding pulse in the CS_2 signal. The read data output from the data buffer after time t4 is not the expected read data to be output from the data buffer. For example, the read data input into the data buffer at time t3 should be output from the data buffer at time t6 (see FIG. 2), but the read data is actually output at time t8. Thus, the data buffer is twisted, and the read data is not output from the data buffer in the same order that the read data was input into the data buffer.

FIG. 5 illustrates an example timing diagram of the first control signal CS_1 and an erroneous second control signal CS_2 that may be generated during read operations. The CS_1 signal begins to toggle between the first signal level and the second signal level at time t0. Read data is input and stored in the data buffer based on each pulse 200, 202, 204, 206, 208, 210 at respective times t0, t1, t3, t5, t7, t9.

The CS_2 signal begins to toggle between the first signal level and the second signal level at time t2. Read data is output from the data buffer based on each pulse 212, 216, 218, 220, 222 at respective times t2, t6, t8, t10, t11. However, the CS_2 signal includes an error. A pulse (i.e., the pulse 214) was not received by the data buffer at time t4 (see FIG. 2), so no read data was output from the data buffer at that time. Thus, each pulse 200, 202, 400, 204, 206, 208, 210 in the CS_1 signal does not have a corresponding pulse 212, 216, 218, 220, 222 in the CS_2 signal. The read data output from the data buffer after time t2 is not the expected read data to be output from the data buffer. For example, the read data output from the data buffer at time t6 should be the read data input into the data buffer at time t3 (see FIG. 2), but the read data output from the data buffer at time t6 was actually input into the data buffer at time t1. Thus, the data buffer is twisted, and the read data is not output from the data buffer in the same order that the read data was input into the data buffer.

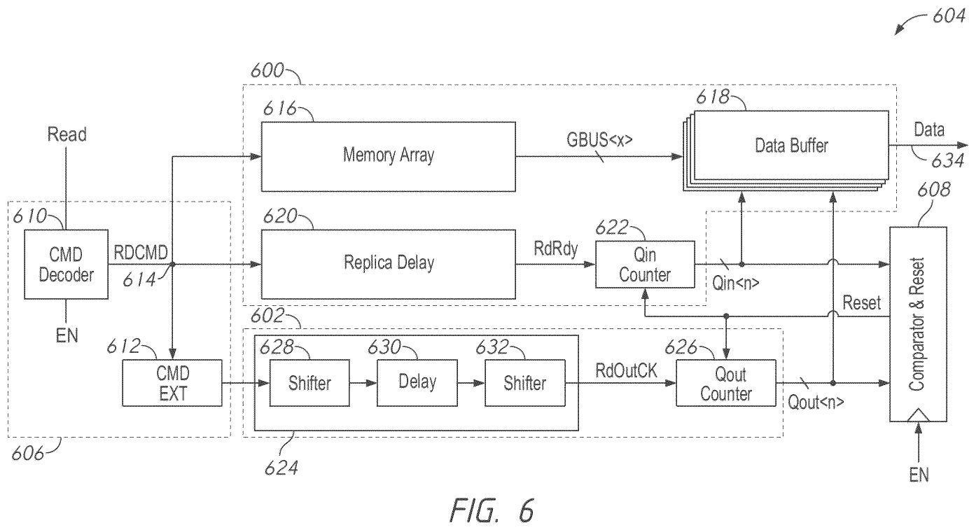

FIG. 6 illustrates a block diagram of an example data path 600 and an example command path 602 for read operations in a memory device 604 according to an embodiment of the disclosure. The memory device 604 may also include command decoder circuitry 606 and comparator and reset circuitry 608. The command decoder circuitry 606 includes a command decoder 610 and a command extender circuit 612, both connected or coupled to a node 614. In some embodiments, the command decoder 610 may be implemented as the command decoder 115 in FIG. 1.

The data path 600 may be configured to read data from a memory array and provide the read data to external data terminals (e.g., the external data terminals DQ of FIG. 1). In FIG. 6, the data path 600 includes a memory array 616 and data buffer 618, and replica delay circuitry 620 and first counter circuit 622. The data buffer 618 may be implemented as a FIFO data buffer that include multiple data storage circuits (represented by multiple boxes for the data buffer 618). One example of a storage circuit is a latch. In some embodiments, the memory array 616 may be implemented as the memory array 150 shown in FIG. 1 with memory banks BANK0-BANKm.

The command decoder circuitry 606 receives internal command signals Read and responsively provides RDCMD signals at the node 614. In some embodiments, each RDCMD signal includes one or more pulses. The RDCMD signals are provided to the memory array 616 and in response data is read out of the memory array 616. The read data is provided to the data buffer 618.

The RDCMD signals are also provided to the replica delay circuitry 620. The replica delay circuitry 620 is configured to replicate the delay that occurs between the memory array 616 receiving a RDCMD signal and the memory array 616 outputting read data based on that RDCMD signal. The replica delay circuitry 620 provides a read ready (RdRdy) signal to the first counter circuit 622. The RdRdy signal can be the first control signal CS_1 in FIGS. 2-5.

The pulses in the RdRdy signal cause the first counter circuit 622 to provide a first count signal Qin on a Qin<n> bus. The Qin signal is received at respective data storage circuits in the data buffer 618. The pulses in the first count signal Qin are used to clock the data buffer 618 to input read data. The process of inputting read data into the data buffer 618 is synchronized with the Qin signal (e.g., rising edges of pulses in the Qin signal). The replica delay circuitry 620 causes the delay time of the RdRdy signal that is input into the first counter circuit 622 to match (or substantially match) the delay time of the read data on the GBUS<x> during read operations.

The command path 602 may be configured to receive RDCMD signals and provide respective control signals for each read operation. The command path 602 includes a timing shift circuit 624 and second counter circuit 626. The timing shift circuit 624 is connected or coupled between the command extender circuit 612 and the second counter circuit 626. In the illustrated embodiment, the timing shift circuit 624 includes a first shifter 628, a delay circuit 630, and a second shifter 632 connected or coupled in series.

The command extender circuit 612 is configured to extend the timing of the RDCMD signal when an RDCMD signal is provided at the node 614. In one embodiment, the command extender circuit 612 extends an RDCMD signal eight (8) internal clock cycles (e.g., eight clock cycles of the LCLK clock of FIG. 1). The timing shift circuit 624 is configured to adjust the timing, of the RDCMD signals prior to the second counter circuit 626. The first shifter 628 is configured to adjust the timing of the RDCMD signals received from the command extender circuit 612 by a first delay. The second shifter 632 is configured to adjust the timing of the RDCMD signals by a second delay and provide read out clock (RdOutCK) signals to the second counter circuit 626. The RdOutCK signal can be the second control signal CS_2 in FIGS. 2-5.

The second shifter 632 adjusts the timing of the RdOutCK signals based on input from the delay circuit 630. In one embodiment, the delay circuit 630 is a delay-locked loop circuit. The timing shift circuit 624 provides the RdOutCK signal having a delay relative to the internal command signal Read so that read data is output from the data buffer 618 to provide the read data from the external DQ terminals (FIG. 1) having a timing that corresponds to a read latency setting relative to the timing of external clocks that are used for timing the provision of the read data by an input/output circuit. The external clocks and the input/output circuit may be the CK_t and CK_c clocks and the input/output circuit 160, respectively, shown in FIG. 1.

The pulses in the RdoutCK signal cause the second counter circuit 626 to provide a second count signal Qout on a Qout<n> bus. The Qout signal is received at respective data storage circuits in the data buffer 618. The pulses in the second count signal Qout are used to clock the data buffer 618 to output read data. The output of the read data from the data buffer 618 is synchronized with the Qout signal (e.g., the rising edges of pulses in the Qout signal).

The comparator and reset circuitry 608 is configured to receive the Qin signal from the first counter circuit 622 and the Qout signal from the second counter circuit 626 and compare count values that are based on the Qin signal and the Qout signal. The read data output from the data buffer 618 is twisted if the count values do not match. The comparator and reset circuitry 608 is further configured to provide a reset signal Reset to the first counter circuit 622 and to the second counter circuit 626. The Reset signal is configured to reset or initialize the first counter circuit 622 and the second counter circuit 626 when there is a mismatch between the count values, which causes both the first counter circuit 622 and the second counter circuit 626 to have the same count value, such as zero (0).

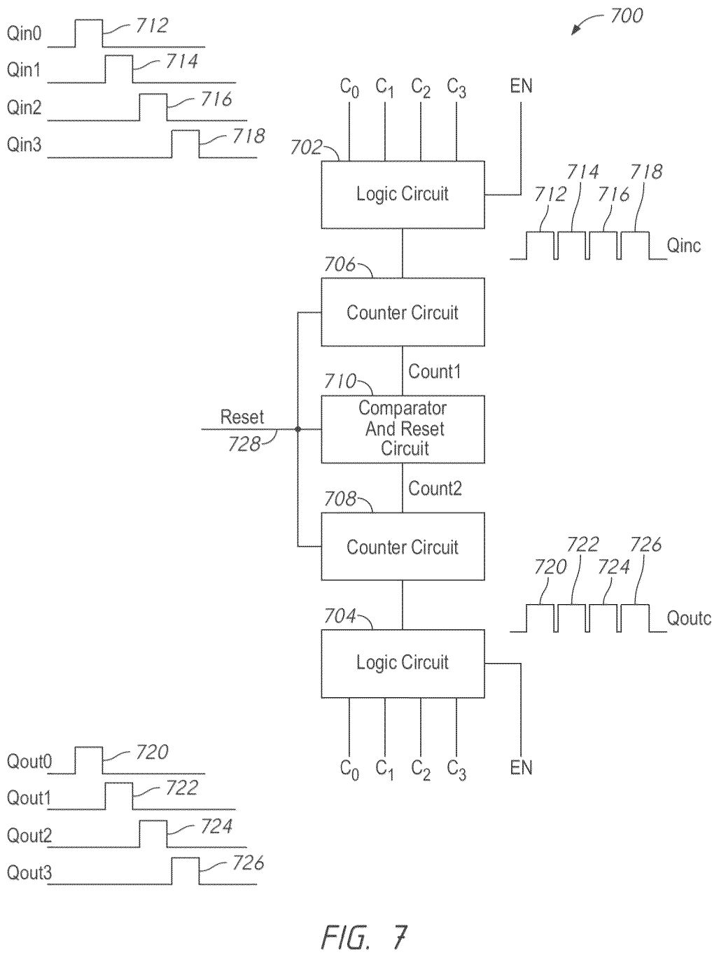

FIG. 7 illustrates a block diagram of example comparator and reset circuitry 700 according to an embodiment of the disclosure. The comparator and reset circuitry 700 may be implemented as the comparator and reset circuitry 608 shown in FIG. 6 in some embodiments. The comparator and reset circuitry 700 includes a first logic circuit 702, a second logic circuit 704, a first counter circuit 706, a second counter circuit 708, and a comparator and reset circuit 710. The first logic circuit 702 is configured to receive a count signal Qin from a counter circuit (e.g., the first counter circuit 622 of FIG. 6). In one embodiment, the first logic circuit 702 receives the staggered pulses of the Qin signal on separate signal lines (e.g., the Qin<n> bus of FIG. 6). For example, in FIG. 7, the count signal Qin0 is received on the signal line C₀, the count signal Qin1 is received on the signal line C₁, the count signal Qin2 is received on the signal line C₂, and the count signal Qin3 is received on the signal line C₃. Although only four signal lines C₀, C₁, C₂, C₃ and four count signals Qin0, Qin1, Qin2, Qin3 are shown in FIG. 7, other embodiments are not limited to this configuration. Any number of signal lines and count signals may be used in other embodiments.

The first logic circuit 702 is configured to combine the Qin0, Qin1, Qin2, Qin3 count signals (e.g., the staggered pulses 712, 714, 716, 718) into a first combined count signal Qinc. The Qinc signal is provided to the first counter circuit 706, which is configured to count the pulses 712, 714, 716, 718 in the Qinc signal (e.g., count the rising edges of the pulses 712, 714, 716, 718). The first counter circuit 706 provides a first count value Count1 to the comparator and reset circuit 710.

The second logic circuit 704 is configured to receive a count signal Qout from a counter circuit (e.g., the second counter circuit 626 of FIG. 6). In one embodiment, the second logic circuit 704 receives the staggered pulses of the count signal Qout on separate signal lines (e.g., the Qout<n> bus of FIG. 6). For example, in FIG. 7, the count signal Qout0 is received on the signal line C₀, the count signal Qout1 is received on the signal line C₁, the count signal Qout2 is received on the signal line C₂, and the count signal Qout3 is received on the signal line C₃. Although only four signal lines C₀, C₁, C₂, C₃ and four count signals Qout0, Qout1, Qout2, Qout3 are shown in FIG. 7, other embodiments are not limited to this configuration. Any number of signal lines and count signals may be used in other embodiments.

The second logic circuit 704 is configured to combine the Qout0, Qout1, Qout2, Qout3 count signals (i.e., the staggered pulses 720, 722, 724, 726) into a second combined count signal Qoutc. The Qoutc signal is provided to the second counter circuit 708, which is configured to count the pulses 720, 722, 724, 726 in the Qoutc signal (e.g., count the rising edges of the pulses 720, 722, 724, 726). The second counter circuit 708 provides a second count value Count2 to the comparator and reset circuit 710.

The comparator and reset circuit 710 is configured to compare the Count1 value and the Count2 value and determine whether the Count1 and the Count2 values match. The comparator and reset circuit 710 is further configured to provide the Reset signal on signal line 728. The Reset signal is received at the counter circuit(s) in the data path, the counter circuit(s) in the command path, the first counter circuit 706, and the second counter circuit 708. The Reset signal is configured to reset or initialize the counter circuit(s) in the data path, the counter circuit(s) in the command path, the first counter circuit 706, and the second counter circuit 708 when the Count1 and the Count2 values do not match, which causes the counter circuit(s) in the data path, the counter circuit(s) in the command path, the first counter circuit 706, and the second counter circuit 708 to all have the same count value (e.g., zero). In one embodiment, the counter circuit(s) in the data path can be implemented as the first counter circuit 622 and the counter circuit(s) in the command path as the second counter circuit 626 shown in FIG. 6.

The comparator and reset circuitry 700 may not operate during read operations but rather during idle periods when read operations are not in process (e.g., periods when the one or more data buffers are not receiving and outputting read data and are in an idle state). The comparator and reset circuitry 700 is further configured to receive an enable signal EN that causes the comparator and reset circuitry 700 to compare the Count1 and the Count2 values and provide the Reset signal if needed. In one embodiment, the EN signal is provided by a command decoder to the first logic circuit 702 and the second logic circuit 704. The command decoder may be implemented as the command decoder 115 of FIG. 1 or the command decoder 610 of FIG. 6.

In some embodiments, the EN signal is implemented as a command that causes read operations to not be performed (e.g., the data buffer(s) not receiving and outputting read data). For example, a power down command, a refresh command, and/or a precharge command may be used to enable the comparator and reset circuitry 700. In an example embodiment of a Double Data Rate 5 Synchronous Dynamic Random-Access Memory (DDR5 SDRAM), a power down entry (PDE) command, an all bank refresh (REFab) command, and/or a precharge (PRE) command may be used as a command to cause the comparator and reset circuitry 700 to operate, to compare the Count1 and the Count2 values, and to provide the Reset signal if needed.

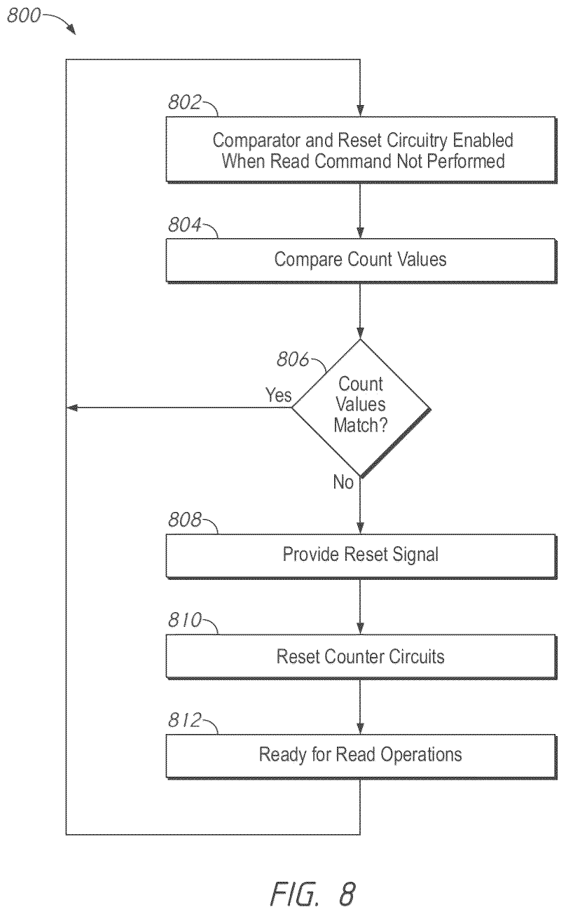

FIG. 8 illustrates a flowchart of an example method 800 of operating a memory device according to an embodiment of the disclosure. Although the method is described in conjunction with one data buffer, such as a FIFO data buffer, the method may be used with multiple data buffers. At block 802, the comparator and reset circuitry is enabled when read operations are not performed. In some embodiments, a command is received that causes read operations to not be performed. The command places the data buffer in an idle state such that read data is not being input and output from the data buffer. Example commands include, but are not limited to, a power down command, a refresh command, and/or a precharge command. In one embodiment, the command is received from a command decoder in the memory device (e.g., the command decoder 115 in FIG. 1).

At block 804, count values that are based on signals received from the command path and the data path in the memory device are compared. In one embodiment, the signal received from the data path is a signal a count value is based on, and the signal received from the command path is a signal another count value is based on. For example, the first counter circuit 622 of FIG. 6 may provide a signal that a count value is based on, and the second counter circuit 626 can provide a signal that another count value is based on.

A determination is made at block 806 as to whether the count values match or if there is a mismatch between the count values. In one embodiment, the comparator and reset circuit 710 shown in FIG. 7 may receive the count values and determine if the count values match or not. A mismatch in the count values indicates the data buffer is twisted. If the count values match, the method returns to block 802.

When a determination is made that the count values do not match, the method continues at block 808 where a reset signal is provided to at least the counter circuit(s) in the command path and to the counter circuit(s) in the data path. In some embodiments, the reset signal is also provided to counter circuits in the comparator and reset circuitry (e.g., first and second counter circuits 706, 708 of FIG. 7).

At block 810, the reset signal resets all of the counter circuits such that the counter circuits output count signals that represent the same count value (e.g., zero). Based on the reset of the counter circuit(s) in the data path and the counter circuit(s) in the command path, the pulses in read data as output from the data buffer correspond to the pulses in read data as input into the data buffer.

The method proceeds to block 812, where the data buffer is ready for the performance of read operations. One or more read operations may be performed after all of the counter circuits are reset. For example, in the embodiments shown in FIG. 6 and FIG. 7, one or more read operations can be performed after the first counter circuit 624, the second counter circuit 628, the first counter circuit 706, and/or the second counter circuit 708 are reset.

The method of FIG. 8 may be performed periodically or at select times and can be used in both test modes and operational modes (e.g., actual operations) of a memory device. Although FIG. 8 depicts particular blocks in a particular order, other embodiments are not limited to this configuration.

The foregoing description, for purposes of explanation, uses specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An apparatus, comprising:
a data buffer configured to receive read data;
a first counter circuit configured to provide a first count signal to the data buffer;
a second counter circuit configured to provide a second count signal to the data buffer; and
a comparator and reset circuitry configured to:
compare a first count value that is based on the first count signal with a second count value that is based on the second count signal; and
provide a reset signal to reset the first counter circuit and the second counter circuit based on a mismatch between the first count value and the second count value.

2. The apparatus of claim 1, wherein the data buffer is a first in, first out data buffer.

3. The apparatus of claim 1, wherein the comparator and reset circuitry comprises:
a comparator and reset circuit;
a third counter circuit configured to receive the first count signal and provide the first count value to the comparator and reset circuit; and
a fourth counter circuit configured to receive the second count signal and provide the second count value to the comparator and reset circuit.

4. The apparatus of claim 1, wherein:
the first counter circuit is included in a data path of the apparatus; and
the second counter circuit is included in a command path of the apparatus.

5. The apparatus of claim 4, wherein the data path further comprises:
a memory array configured to provide read data to the data buffer during read operations; and
a replica delay circuit configured to replicate delay that occurs in the memory array prior to provision of the read data to the data buffer.

6. The apparatus of claim 4, further comprising command decoder circuitry comprising:
a command decoder configured to provide read command signals to the data path and the command path; and
a command extender circuit configured to extend a timing of each read command signal provided to the command path.

7. The apparatus of claim 6, wherein the command decoder is further configured to provide a command to the comparator and reset circuitry to enable the comparator and reset circuitry to compare the first and the second count values and provide the reset signal based on the mismatch between the first and the second count values.

8. The apparatus of claim 6, wherein the command path further comprises a time shifting circuit operably coupled between the command extender circuit and the second counter circuit to shorten the timing of the read command signals.

9. An apparatus, comprising:
a first in, first out (FIFO) data buffer;
a data path, the data path comprising a first counter circuit configured to provide a first count signal to the FIFO data buffer to input read data into the FIFO data buffer;
a command path, the command path comprising a second counter circuit configured to provide a second count signal to the FIFO data buffer to output the read data from the FIFO data buffer; and
a comparator and reset circuitry configured to:
compare a first count value that is based on the first count signal with a second count value that is based on the second count signal; and
provide a reset signal to reset the first counter circuit and the second counter circuit based on a mismatch between the first count value and the second count value.

10. The apparatus of claim 9, wherein the data path further comprises a memory array.

11. The apparatus of claim 10, further comprising a command decoder configured to provide read command signals to the command path and the data path for read operations, wherein data is read out of the memory array based on the read command signals.

12. The apparatus of claim 11, wherein the command decoder is further configured to provide a command to the comparator and reset circuitry to enable the comparator and reset circuitry to compare the first and the second count values and provide the reset signal based on the mismatch between the first and the second count values.

13. The apparatus of claim 9, wherein the comparator and reset circuitry comprises:
a comparator and reset circuit;
a third counter circuit configured to receive the first count signal and provide the first count value to the comparator and reset circuit; and
a fourth counter circuit configured to receive the second count signal and provide the second count value to the comparator and reset circuit.

14. The apparatus of claim 9, wherein the data path further comprises a replica delay circuit operably coupled between a command decoder and the first counter circuit.

15. The apparatus of claim 9, wherein:
the command path further comprises a timing shift circuit operably coupled between a command extender circuit and the second counter circuit; and
the command extender circuit is operably coupled to a command decoder.

16. The apparatus of claim 9, further comprising an input/output circuit operably coupled to the FIFO data buffer.

17. A method of operating a memory device, the method comprising:
receiving a command that causes a data buffer in the memory device to be placed in an idle state;
comparing a first count value that is based on a first count signal received from a first counter circuit in a data path of the memory device with a second count value that is based on a second count signal received from a second counter circuit in a command path of the memory device; and
based on a mismatch between the first count value and the second count value, providing a reset signal to the first counter circuit and the second counter circuit to reset the first counter circuit and the second counter circuit.

18. The method of claim 17, further comprising based on a match between the first count value and the second count value, subsequently performing one or more read operations.

19. The method of claim 17, further comprising performing one or more read operations after the first counter circuit and the second counter circuit are reset.

20. The method of claim 17, wherein the command comprises at least one of a power down command, a refresh command, or a precharge command.

21. The method of claim 17, wherein the data buffer is a first in, first out data buffer.

22. An apparatus comprising:
a first counter circuit configured to provide a first count signal to a first in, first out (FIFO) data buffer to input read data into the FIFO data buffer;
a second counter circuit configured to provide a second count signal to the FIFO data buffer to output the read data from the FIFO data buffer; and
a comparator and reset circuitry configured to:
compare a first count value that is based on the first count signal with a second count value that is based on the second count signal; and
provide a reset signal to reset the first counter circuit and the second counter circuit based on a mismatch between the first count value and the second count value.

23. The apparatus of claim 22, wherein the comparator and reset circuitry comprises:
a comparator and reset circuit;
a third counter circuit configured to receive the first count signal and provide the first count value to the comparator and reset circuit; and
a fourth counter circuit configured to receive the second count signal and provide the second count value to the comparator and reset circuit.

24. The apparatus of claim 22, wherein:
the first counter circuit is included in a data path;
the data path further comprises:
a memory array configured to provide read data to the data buffer during read operations; and
a replica delay circuit configured to replicate delay that occurs in the memory array prior to provision of the read data to the data buffer;
the second counter circuit is included in a command path; and
the command path further comprises a time shifting circuit operably coupled between the command extender circuit and the second counter circuit to shorten the timing of the read command signals.

25. The apparatus of claim 22, further comprising command decoder circuitry comprising:
a command decoder configured to provide read command signals to the data path and the command path; and
a command extender circuit configured to extend a timing of each read command signal provided to the command path,
wherein the command decoder is further configured to provide a command to the comparator and reset circuitry to enable the comparator and reset circuitry to compare the first and the second count values and provide the reset signal based on the mismatch between the first and the second count values.
